(19) United States
(12) Patent Application Publication
(10) Pub. No.: US 2026/0198337 A1
(43) Pub. Date: Jul. 9, 2026

(54) HETEROGENOUS GLASS CORE VIAS FOR INTEGRATED SEMICONDUCTOR PACKAGES

(71) Applicant: Intel Corporation, Santa Clara, CA (US)

(72) Inventors: Vinith Bejugam, Mesa, AZ (US); Yonggang Li, Chandler, AZ (US); Dhruba Pattadar, Chandler, AZ (US); Hanyu Song, Chandler, AZ (US); Amm Hasib, Chandler, AZ (US); Bai Nie, Chandler, AZ (US); Mao-Feng Tseng, Tempe, AZ (US); Mohammad Mamunur Rahman, Gilbert, AZ (US); Srinivas Pietambaram, Chandler, AZ (US); Samuel George, Chandler, AZ (US); Jason Bradley, Tempe, AZ (US); Whitney Bryks, Tempe, AZ (US); Nevin Erturk, Atlanta, GA (US)

(73) Assignee: Intel Corporation, Santa Clara, CA (US)

(21) Appl. No.: 19/011,347

(22) Filed: Jan. 6, 2025

(51) Int. Cl. H01L 23/538; H01L 21/48; H01L 23/15; H01L 23/498

(52) U.S. Cl. CPC H10W 70/611; H10W 70/095; H10W 70/635; H10W 70/65; H10W 70/69; H10W 70/692

(57) ABSTRACT

Heterogenous through glass vias, and related packages, apparatuses, systems, and methods of fabrication are discussed. A glass substrate of a package has a first surface, an opposing second surface, and any number of first and second holes extending at partially between the first and second surfaces. Via metallizations within the first holes are heterogenous with respect to via metallizations within the second holes such that they have different lateral widths, lateral shapes, tapers, or any combination thereof.

### BACKGROUND

Higher performance, lower cost, increased miniaturization, greater packaging density, and increased product flexibility of integrated circuit (IC) devices are ongoing goals of the electronics industry. IC packaging is a stage of semiconductor or IC device fabrication in which an IC that has been monolithically fabricated on a chip (or die) is assembled into a package that protects the IC chip from physical damage and communicatively connects the IC to other packaged IC chips and/or a scaled host component, such as a package substrate, or a printed circuit board. Multiple chips can be co-assembled, for example, into a multi-die package (MCP). Some package architectures include an IC die attached to a glass substrate and coupled to electrically conductive through-glass vias (TGVs) extending through the glass substrate. Glass substrates have advantages such as low dielectric loss, high thermal stability, and improved surface planarity and surface quality. However, current TGVs may have the same sizes and characteristics, which limits package flexibility and integration. It is with respect to these and other considerations that the present improvements have been needed. Such improvements may become critical as the desire to deploy high-performance IC packages in various devices and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating example methods for fabricating and assembling glass substrate structures having heterogeneous through glass vias;

FIGS. 2, 3, 4, 5, 6, 7, 10, 13, 14, 15, 16, 17, 18, 19, and 20 are illustrations of cross-sectional side views of glass substrate structures as the methods of FIG. 1 are practiced to form heterogenous through glass vias;

FIGS. 8, 11, and 12 are top-down views of the glass substrate structures illustrating heterogeneous through glass via sizes and shapes;

FIG. 9 is a top-down view of laser emission patterns of the methods of FIG. 1 to form heterogeneous through glass vias;

FIGS. 21, 22, and 23 are illustrations of cross-sectional side views of package structures as methods are practiced to assemble a package assembly having a glass substrate with heterogeneous through glass vias;

FIG. 24 illustrates exemplary systems employing an IC assembly including a glass core substrate with heterogenous through glass vias; and

FIG. 25 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/-10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Apparatuses, systems, and methods are described herein related to heterogeneous through glass vias within a glass core substrate, which may be deployed in an IC package, assembly, or the like.

As described above, current package architectures may include one or more IC dies attached to a glass substrate and coupled to electrically conductive through-glass vias (TGVs) extending through the glass substrate. However, current TGVs may have the same sizes and characteristics, which limits integration of glass substrates in some package architectures. Embodiments discussed herein provide TGVs with differing characteristics such as cross-sectional widths, taper angles, cross-sectional shapes, and the like. Such heterogenous TGVs provide flexibility and customization within the package architecture. Different pathways for obtaining mixed or heterogenous via structures in a glass core substrate are discussed. In some embodiments, the base via formation process includes laser-assisted etching (LAE), where different pulse energies of a Bessel beam in a pico-second regime are deployed to modify a glass substrate by forming nanochannels and densified zones that have enhanced etch rate in non-isotropic fashion compared to the bulk glass of the glass substrate. These regions are subsequently etched in base (e.g., NaOH, KOH) or acidic (e.g., HF) solution to form TGVs of different characteristics such as different sizes, different tapers, and different cross-sectional shapes. Other techniques include application of a layer of differing thicknesses applied over the glass substrate such that the layer absorbs some of the laser light, which varies depending on the thickness over the via site such that the resultant TGV taper is controlled using the thickness of the layer and/or whether the layer is applied.

The resultant glass substrates having heterogenous TGVs provide a variety of advantages including customization, seamless heterogeneous integration, enhanced functionality, design flexibility, flexible power distribution and signal integrity, and others.

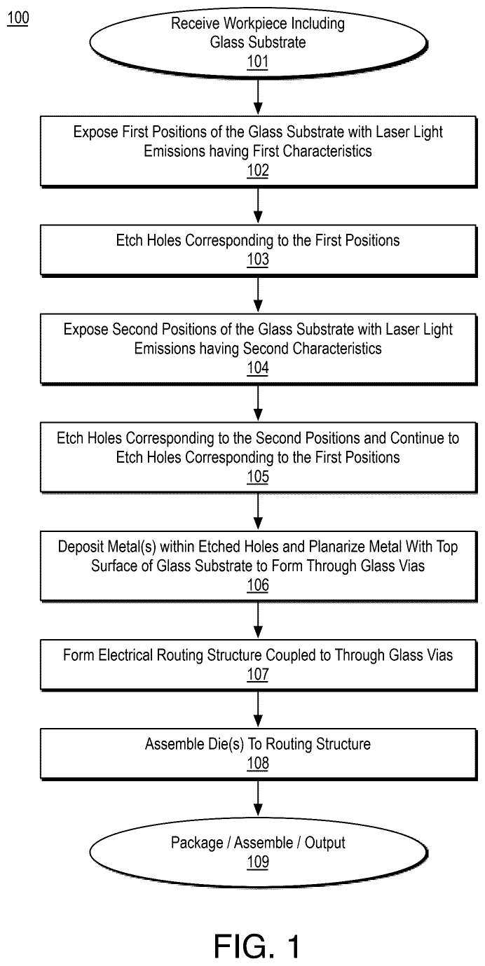

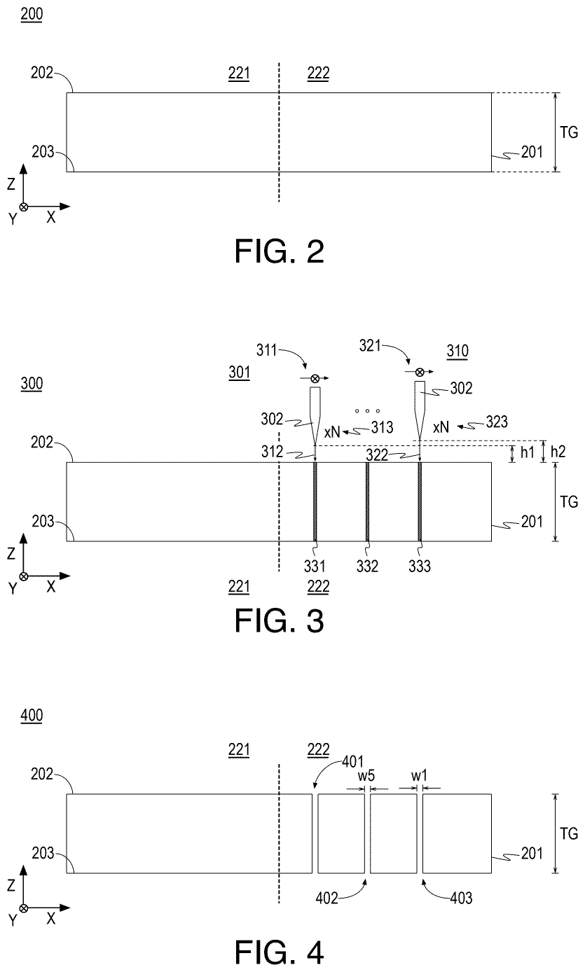

FIG. 1 is a flow diagram illustrating example methods 100 for fabricating and assembling glass substrate structures having heterogeneous through glass vias, arranged in accordance with at least some implementations of the present disclosure. For example, methods 100 may be implemented to fabricate any glass substrates structures, package structures, or assemblies discussed herein. In the illustrated embodiment, methods 100 include one or more operations as illustrated by operations 101-109. However, embodiments herein may include additional operations, certain operations being omitted, or operations being performed out of the order provided. FIGS. 2-23 illustrate structures and components as methods 100 are practiced.

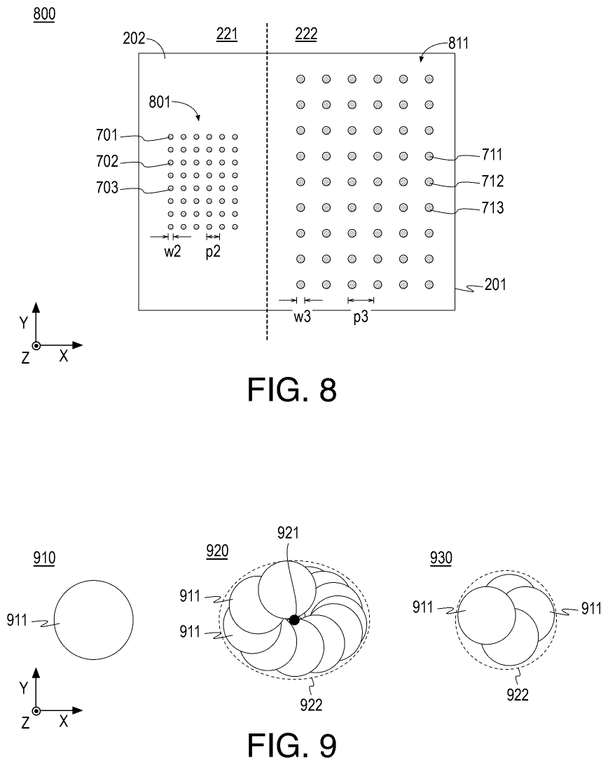

FIGS. 2, 3, 4, 5, 6, 7, 10, 13, 14, 15, 16, 17, 18, 19, and 20 are illustrations of cross-sectional side views of glass substrate structures as methods 100 are practiced to form heterogenous through glass vias, arranged in accordance with at least some implementations of the present disclosure. FIGS. 8, 11, and 12 are top-down views of the glass substrate structures illustrating heterogeneous through glass via sizes and shapes, arranged in accordance with at least some implementations of the present disclosure. FIG. 9 is a top-down view of laser emission patterns of methods 100 to form heterogeneous through glass vias, arranged in accordance with at least some implementations of the present disclosure. FIGS. 21, 22, and 23 are illustrations of cross-sectional side views of glass substrate structures as methods 100 are practiced to assemble a package assembly having a glass substrate with heterogeneous through glass vias, arranged in accordance with at least some implementations of the present disclosure.

Methods 100 begins at operation 101, where a workpiece such as a glass substrate including a thickness of glass is received. The workpiece may be prepared upstream of methods 100 and may be in a large panel format, a wafer format, or the like. In addition to the thickness of glass, the workpiece received at operation 101 may include one or more materials upon which electrical routing structures may be formed.

FIG. 2 is an illustration of a cross-sectional side view of a glass substrate structure 200 including materials received for processing such as a glass substrate 201 having a front or first surface 202, an opposing back or second surface 203, and a thickness TG extending between first surface 202 and second surface 203, and orthogonal to both. IC device package structures may be advantageously fabricated upon glass substrate 201 as flatness and/or thickness control for a preform of glass is superior to that of starting substrates based on organic materials (e.g., epoxy), and costs can be significantly lower than for monocrystalline materials (e.g., silicon).

Glass substrate 201 is a solid bulk material layer that may have been previously formed into any shape in plan view (e.g., x-y plane) suitable for a packaging workpiece, such as a rectangular shape. Glass substrate 201 has a thickness TG that may vary with implementation, for example, to limit warpage while remaining thin enough to permit the formation of through glass vias. In some embodiments, thickness TG is not less than 100 μm and not more than 2000 μm. In some embodiments, thickness TG is advantageously not less than 400 μm and not more than 1000 μm.

In some embodiments, glass substrate 201 is predominantly silicon and oxygen. In some embodiments, glass substrate 201 includes at least 23 percent silicon and at least 26 percent oxygen, by weight (i.e., wt. %). Glass substrate 201 may further include one or more additives, such as, Aluminum, Boron, Magnesium, Calcium, Barium, Tin, Sodium, Potassium, Strontium, Phosphorus, Zirconium, Lithium, Titanium, or Zinc. In embodiments where glass substrate 201 includes at least 23 wt. % Si and at least 26 wt. % O, glass substrate 201 may further include at least 5 wt. % Al. Additives within glass substrate 201 may form suboxides (A₂O) monoxides (AO), binary oxides (AO₂), ternary oxides (ABO₃), and mixtures thereof. For example, glass substrate 201 may include AlOₓ (e.g., Al₂O₃), BOₓ (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ(e.g., P₂O₃), ZrOₓ (e.g., ZrO₂), LiOₓ (e.g., Li₂O), TiOₓ (e.g., TiO₂), or ZnOₓ (e.g., ZnO₂). In some embodiments, glass substrate is a BF33 glass. Depending on chemical composition, glass substrate 201 may therefore be referred to as silica, fused silica, aluminosilicate, borosilicate, or alumino-borosilicate, for example.

In some embodiments, glass substrate 201 is advantageously a bulk material of substantially homogeneous composition in contrast to a composite material that may merely include glass fillers and/or fibers. Although glass substrate 201 is substantially amorphous in some embodiments, glass substrate 201 may also have other morphology or microstructure, such as polycrystalline (e.g., nanocrystalline). In some embodiments, glass substrate 201 is rectangular in shape in plan view. However, other shapes may be used. In some embodiments, glass substrate 201 is a layer of glass having a thickness of not less than 50 μm, a first length of not less than 10 mm and a second length orthogonal to the first length of not less than 10 mm. In some embodiments, glass substrate 201 is absent any organic adhesive or other organic material. Although not depicted, one or more material layers may clad either or both of first surface 202 and second surface 203 of glass substrate 201 so that glass substrate 201 is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of glass substrate 201. Organic material layers, such as polymer dielectric materials, may also clad one or more sides of glass substrate 201. Hence, while glass substrate 201 is advantageously substantially free of organic materials (e.g., no adhesives, etc.), a workpiece may include organic within a substrate stack that includes glass substrate 201. Such claddings or build-up layers may be fabricated on glass substrate 201 as discussed herein below. As shown, glass substrate 201 may include any number of regions 221, 222 where through glass vias having differing characteristics are to be fabricated.

Returning to FIG. 1, methods 100 continue at operation 102, where first positions of the glass substrate are exposed with laser light emissions. In some embodiments, the positional accuracy of the exposure is about ±5 μm. Such exposures may be performed at any number of positions and the exposures may be substantially the same at each position, or they may be different. As discussed herein, the different exposure conditions cause different resultant through glass vias having different characteristics such as different cross-sectional widths, taper angles, cross-sectional shapes, etc. Notably, methods 100 provide for a first exposure and etch cycle and a second exposure and etch cycle. Those positions that are exposed in the first exposure are twice etched while those exposed in the second exposure are etched once. The twice etched locations (i.e., etched twice after one laser modification) are etched to a larger cross-sectional width and may have other different characteristics while those etched once (i.e., etched once after a single laser modification) are etched to a relatively smaller cross-sectional width and may have other different characteristics.

Within each of the first and/or second exposures, however, different conditions can be provided for each of the locations. Such different conditions include different exposure conditions inclusive of number of pulses, single or multiple distances from the glass surface, exposure intensity, duration, providing multiple exposures in a lateral pattern, and others. Furthermore, the different conditions may include application of a semi-laser light absorbent surface coating and/or different thickness of the semi-laser light absorbent surface coating. These differences may be deployed within the same exposure sets (i.e., those exposures performed before and between etch processes) and/or between the different exposure sets. Although two exposure sets and corresponding etches are illustrated, methods 100 may include any number of such exposure sets and corresponding etches such as a single exposure/etch, three exposure sets and corresponding etches, four exposure sets and corresponding etches, or more.

With continued reference to operation 102, a plurality of first positions of a glass substrate are each exposed with a laser light emission. As discussed, each of the first positions may be exposed with the same laser light emission conditions, or they may differ. The exposure may be with any suitable wavelength of light such as with a laser light emission in the range of 300 to 1100 nm.

FIG. 3 is an illustration of a cross-sectional side view of a glass substrate structure 300 similar to glass substrate structure 200 after and during exposure processing to form modified glass regions 331, 332, 333 within region 222 of glass substrate 201. Notably, each exposure modifies glass substrate 201 makes it prone to faster etching by, for example, changing the refractive index of the exposed glass, altering the density of the exposed glass, and/or breaking bonds within the exposed regions to form modified glass regions 331, 332, 333 having different characteristic than the remaining bulk of glass substrate 201.

As shown, each exposure may have the same or differing exposure conditions such as exposure conditions 301, 310. Notably, exposure to form glass substrate structure 300 may expose those modified glass regions 331, 332, 333 that are to be larger vias in a first exposure set. In some embodiments, such exposures are performed using the same conditions at each position. In some embodiments, the exposure conditions 301, 310 include a number of exposures, which may be a single shot exposure or multiple exposures; a depth of focus (DoF) of the single shot exposure more each of the multiple exposures; an energy of the single shot exposure more each of the multiple exposures (which may be expressed as a percentage of full exposure capability); a pattern of multiple exposures (if deployed); and others. As will be appreciated, such exposure conditions may vary the resultant modified glass regions 331, 332, 333 and eventual through glass vias.

In the context of glass substrate structure 300, a first exposure is performed by a laser source 302 using exposure conditions 301, which provides one or more laser exposures 312 on a x, y position corresponding to modified glass region 331. Exposure conditions 301 include a power of one or more laser exposures 312, a distance or height h1 from first surface 202 during each of one or more laser exposures 312, a number of exposures 313 (if multiple exposures are deployed), and a lateral pattern 311 (if deployed) laterally across first surface 202. It is noted other exposure conditions 301 may be modified such as focal length, aperture or beam size, and others. Lateral pattern 311 is discussed further herein and includes small (i.e., a fraction of or up to the width of the modified glass region being formed) movements of glass substrate 201 relative to laser source 302, such as trepanning, in the x-y plane that may modify the cross-sectional shape of modified glass regions 331, 332, 333.

Similarly, any number of additional exposures are performed by laser source 302, including a second exposure, which provides one or more laser exposures 322 on a different x, y position corresponding to modified glass region 333. Exposure conditions 310 again include a power of one or more laser exposures 322, a distance or height h2 from first surface 202 during each of one or more laser exposures 322, a number of exposures 323 (if multiple exposures are deployed), and a lateral pattern 321 (if deployed), focal length, aperture or beam size, and so on.

In some embodiments, exposure conditions 301, 310 include one of a single shot exposures at height h1 of 1.3 mm at 70% power; a cycle of exposures including a first shot at height h1 of 1.3 mm at 70% power and a second shot at height h2 of 1.2 mm at 75% power; a cycle of exposures including a first shot at height h1 of 1.3 mm at 75% power and a second shot at height h2 of 1.2 mm at 75% power; or a cycle of exposures including a first shot at height h1 of 1.3 mm at 65% power and a second shot at height h2 of 1.2 mm at 75% power. Of course, many adjustments can be made to impact the resultant modified glass regions 331, 332, 333 and eventual through glass vias. The characteristics of the resultant through glass vias are discussed herein below and generally correspond to the resultant etched openings or holes.

Returning to FIG. 1, methods 100 continue at operation 103, where holes are etched corresponding to the first positions of the glass substrate exposed at operation 102. The etch performed at operation 103 may be any suitable etch such as a wet etch in a base (e.g., NaOH, KOH) solution or acidic (e.g., HF) solution. In some embodiments, the etch at operation 103 is a 80-130° C. etch using 25-50% NaOH. Notably, the etch at operation 103 may be non-isotropic and may be performed from one or both sides of the glass substrate. Etch from both sides may form a characteristic double taper profile in some contexts. Notably, the multiple exposure and etch process discussed with respect to methods 100 may allow for larger width through glass vias for those vias once exposed and twice etched and smaller width through glass vias for those vias once exposed and once etched.

FIG. 4 is an illustration of a cross-sectional side view of a glass substrate structure 400 similar to glass substrate structure 400 after etch processing to remove all or portions of modified glass regions 331, 332, 333 as well as adjacent un-modified regions of glass substrate 201 to form openings 401, 402, 403. Openings 401, 402, 403, which may also be characterized as holes, may extend entirety through the thickness of glass substrate 201 or partially through the thickness of glass substrate 201 to form blind vias. As discussed, the etch processing may be a wet etch in a base (e.g., NaOH, KOH) solution or acidic (e.g., HF) solution. Although not illustrated in FIG. 4, in some embodiments, openings 401, 402, 403 may include a taper such as a dual taper, as illustrated herein below. In the context of glass substrate structure 400 each resultant opening width such as widths w1 and w5 may be the same, or they may be different. Furthermore, the lateral cross-sectional shape of each of openings 401, 402, 403 may be the same or they may be different. In contexts where each location has the same exposure, it is expected that openings 401, 402, 403 will be substantially the same. However, larger openings and/or different shaped openings (i.e., heterogeneous openings 401, 402, 403) may be formed using the different exposure settings discussed herein. It is noted the variation of resultant through glass vias is discussed herein below.

Returning to FIG. 1, methods 100 continue at operation 104, where second positions of the glass substrate are exposed with laser light emissions. Such exposures may be performed at any number of positions and the exposures may be substantially the same at each position, or they may be different. Furthermore, the exposures may be the same as those performed at operation 102, or they may be different. Different exposure conditions performed at operation 104 may again cause different resultant through glass vias having different characteristics such as different cross-sectional widths, taper angles, cross-sectional shapes, etc. Such different may be within those exposed at operation 104 and/or between those exposed at operation 102. As discussed, those positions exposed at operation 102 are twice etched (at operations 103, 105) while those exposed at operation 104 are etched once (at operation 105). The twice etched locations may be etched to larger cross-sectional widths and may have other different characteristics while those etched once are etched to a relatively smaller cross-sectional widths and may have other different characteristics.

Furthermore, at operation 104, the same or different exposure conditions may be provided for each of the locations. Such different exposure conditions include those discussed above, such as number of pulses, single or multiple distances from the glass surface, exposure intensity, duration, application of a semi-laser light absorbent surface coating and/or different thickness of the semi-laser light absorbent surface coating, etc. As discussed, a plurality of second positions of a glass substrate are each exposed with a laser light emission. Each of the second positions may be exposed with the same laser light emission conditions, or they may differ. The exposure may be with any suitable wavelength of light such as with a laser light emission of 515 nm.

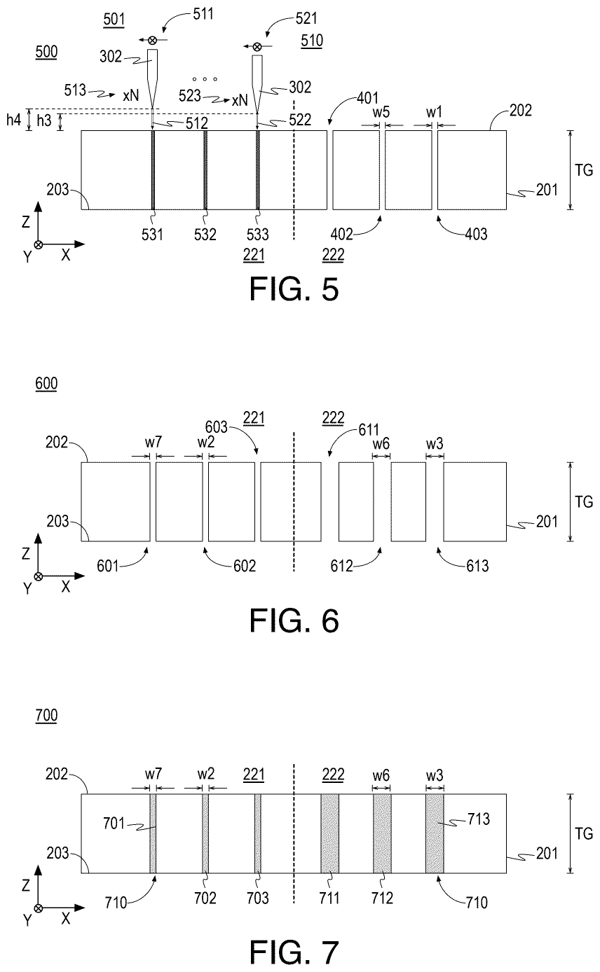

FIG. 5 is an illustration of a cross-sectional side view of a glass substrate structure 500 similar to glass substrate structure 400 after and during exposure processing to form modified glass regions 531, 532, 533 within region 221 of glass substrate 201. Notably, each exposure modifies glass substrate 201 makes it prone to faster etching as discussed with respect to modified glass regions 331, 332, 333. As shown, each exposure may have the same or differing exposure conditions such as exposure conditions 501, 510. Notably, exposure to form glass substrate structure 500 may expose those modified glass regions 531, 532, 533 that are to be smaller vias in a second exposure set due to being etched once using methods 100.

In some embodiments, the exposures illustrated with respect to glass substrate structure 500 are performed using the same conditions at each position. In some embodiments, the exposure conditions 501, 510 include a number of exposures, which may be a single shot exposure or multiple exposures; a depth of focus (DoF) of the single shot exposure more each of the multiple exposures; an energy of the single shot exposure more each of the multiple exposures (which may be expressed as a percentage of full exposure capability); a pattern of multiple exposures (if deployed); and others. As will be appreciated, such exposure conditions may vary the resultant modified glass regions 531, 532, 533 and eventual through glass vias.

As shown, a first exposure is performed by laser source 302 using exposure conditions 501, which provides one or more laser exposures 512 on a x, y position corresponding to modified glass region 531. Exposure conditions 501 include a power of one or more laser exposures 512, a distance or height h4 from first surface 202 during each of one or more laser exposures 512, a number of exposures 513 (if multiple exposures are deployed), and a lateral pattern 511 (if deployed) across first surface 202, focal length, aperture or beam size, and others. Similarly, any number of additional exposures are performed by laser source 302, including a second exposure, which provides one or more laser exposures 522 on a different x, y position corresponding to modified glass region 533. Exposure conditions 510 again include a power of one or more laser exposures 522, a distance or height h3 from first surface 202 during each of one or more laser exposures 522, a number of exposures 523 (if multiple exposures are deployed), and a lateral pattern 521 (if deployed), focal length, aperture or beam size, and so on.

In some embodiments, exposure conditions 501, 510 include one of a single shot exposures at height h1 of 1.3 mm at 70% power; a cycle of exposures including a first shot at height h3 of 1.3 mm at 70% power and a second shot at height h4 of 1.2 mm at 75% power; a cycle of exposures including a first shot at height h3 of 1.3 mm at 75% power and a second shot at height h4 of 1.2 mm at 75% power; or a cycle of exposures including a first shot at height h3 of 1.3 mm at 65% power and a second shot at height h4 of 1.2 mm at 75% power. As discussed above, a variety of adjustments can be made to impact the resultant modified glass regions 531, 532, 533 and eventual through glass vias. The characteristics of the resultant through glass vias are discussed herein below and generally correspond to the resultant etched openings or holes.

In some embodiments, exposure conditions 501, 510 include one of a single shot exposures at height h1 at power P1; a cycle of exposures including a first shot at height h1 at power P1 and a second shot at a height h2~0.9×b 1 at a power of P2~1.07×b 1; a cycle of exposures including a first shot at height h1 at power P2 and a second shot at height h2 at power P2; or a cycle of exposures including a first shot at height h1 at a power of 0.93×P1 and a second shot at height h2 at power P1. Other power and height ratios may be used. As discussed above, a variety of adjustments can be made to impact the resultant modified glass regions 531, 532, 533 and eventual through glass vias. The characteristics of the resultant through glass vias are discussed herein below and generally correspond to the resultant etched openings or holes.

Returning to FIG. 1, methods 100 continue at operation 105, where holes are etched corresponding to the second positions of the glass substrate exposed at operation 104 and the holes opened at operation 103 are enlarged by the second etch processing such that the etches are simultaneous. The etch performed at operation 103 may be any suitable etch such as a wet etch in a base (e.g., NaOH, KOH) solution or acidic (e.g., HF) solution. In some embodiments, the etch at operation 103 is a 80-130° C. etch using 25-50% NaOH. The etch at operation 103 may be non-isotropic and may be performed from one or both sides of the glass substrate with etching from both sides forming a double taper profile in some contexts. The etches performed at operations 103, 105 may be the same or they may be different.

FIG. 6 is an illustration of a cross-sectional side view of a glass substrate structure 600 similar to glass substrate structure 500 after etch processing to remove all or portions of modified glass regions 531, 532, 533 (and optionally adjacent un-modified regions of glass substrate 201 to form openings 601, 602, 603) while such etch processing expands openings 401, 402, 403 to expanded openings 611, 612, 613. Openings 601, 602, 603 and/or openings 611, 612, 613 may extend entirety through the thickness of glass substrate 201 (as shown) or partially through the thickness of glass substrate 201 to form blind vias. Although not illustrated in FIG. 6, in some embodiments, openings 601, 602, 603 and/or openings 611, 612, 613 may include a taper such as a dual taper, as illustrated herein below.

In the context of glass substrate structure 600, each resultant opening width of openings 611, 612, 613 in region 222 such as widths w3 and w6 as well as the lateral cross-sectional shape of each of openings 611, 612, 613 may be the same, or they may be different, as influenced by the exposure processing discussed with respect to FIG. 3. Similarly, in the context of region 221 of glass substrate 201, each opening 601, 602, 603 may have the same width such that widths w2 and w7 are the same, or they may be different. Furthermore, the lateral cross-sectional shape of each of openings 601, 602, 603 may be the same or they may be different. In contexts where each location within region 221 has the same exposure, it is expected that openings 601, 602, 603 will be substantially the same. However, larger openings and/or different shaped openings (i.e., heterogeneous openings 601, 602, 603) may be formed using the different exposure settings discussed herein. In any event, due to the multiple etch processing operations performed on openings 611, 612, 613 relative to the single etch processing performed on openings 601, 602, 603, openings 611, 612, 613 have a greater cross-sectional width than those openings 601, 602, 603 (i.e., w3>w7, w3>w2, w6>w7, and w6>w2). The variation of resultant through glass vias is discussed herein below, which correspond to openings 601, 602, 603, 611, 612, 613 are discussed herein below.

Returning to FIG. 1, methods 100 continue at operation 106, where a suitable metal is deposited within the openings or holes to form electrically conductive through vias. The metal may be deposited using any suitable technique or techniques such as plating. In some embodiments, a seed plating layer is formed followed by bulk plating operations. The metal may be a single material or multiple materials. The resultant metallization structures may be characterized as through substrate vias (TSVs) or through glass vias (TGVs). The via metallization may be planarized to remove overburden associated with the plating process to form through glass vias that have surfaces that are coplanar with the top and bottom surfaces of the glass substrate.

FIG. 7 is an illustration of a cross-sectional side view of a glass substrate structure 700 similar to glass substrate structure 600 after formation of a metallization 710 to form through glass vias 701, 702, 703 in region 221 of glass substrate 201 and through glass vias 711, 712, 713 in region 222 of glass substrate 201. Metallization 710 may be a single or multiple layers and may include any suitable metals such as a copper fill. In some embodiments, metallization 710 is deposited over first surface 202 and second surface 203 and into openings 601, 602, 603, 611, 612, 613. In some embodiments, metallization 710 is formed on a seed layer (not shown). Metallization 710 may be in direct contact with sidewalls of openings 601, 602, 603, 611, 612, 613 and may, but need not, substantially fill openings 601, 602, 603, 611, 612, 613. In some examples, metallization 710 is one or more metals (e.g., predominantly copper) deposited (e.g., electroplated) upon surfaces of the workpiece. As discussed, after deposition, planarization processing may be performed to remove overburden from first surface 202 and second surface 203 such that metallization 710 remains only within and adjacent to sidewalls of openings 601, 602, 603, 611, 612, 613 to form through glass vias 701, 702, 703 in region 221 and through glass vias 711, 712, 713 in region 222.

As discussed, although illustrated as the same in FIG. 7, by varying exposure conditions, the lateral widths w2, w7 of through glass vias 701, 702, 703 may be varied within region 221 and/or the lateral widths w3, w6 of through glass vias 711, 712, 713 may be varied within region 222. In some embodiments, width w6 is not less than 5% greater than width w3. In some embodiments, width w6 is not less than 10% greater than width w3. In some embodiments, width w6 is not less than 20% greater than width w3. Similarly, in various embodiments, width w7 is not less than 5%, not less than 10%, or not less than 20% greater than width w2. In some embodiments, widths w3, w6 are in the range of about 35 to 60 μm and widths w2, w7 are in the range of about 20 to 40 μm. As discussed below, greater variation may be attained using the discussed multi-etch techniques.

FIG. 8 is a top-down view of a glass substrate structure 800 such as glass substrate structure 700 having through glass vias 701, 702, 703 in region 221 and through glass vias 711, 712, 713 in region 222 of glass substrate 201. Notably, through glass vias 701, 702, 703 and heterogeneous through glass vias 711, 712, 713 may be in any suitable layout such as a grid 801 of through glass vias 701, 702, 703 and a grid 811 of through glass vias 711, 712, 713. However, other layouts may be used. In the context of glass substrate structure 800, through glass vias 701, 702, 703 are homogeneous, as are through glass vias 711, 712, 713. That is, grid 801 includes through glass vias 701, 702, 703 of substantially the same sizes and shapes and grid 811 includes through glass vias 711, 712, 713 of substantially the same sizes and shapes. However, as discussed, in some embodiments, grid 801 includes heterogenous through glass vias 701, 702, 703 of different sizes and/or shapes and/or grid 811 includes heterogenous through glass vias 711, 712, 713 of different sizes and/or shapes.

In some embodiments, double etch of the holes containing through glass vias 711, 712, 713 causes the lateral widths w3 (i.e., diameters) of through glass vias 711, 712, 713 to be greater than the lateral widths w2 (i.e., diameters) of through glass vias 701, 702, 703. In some embodiments, width w3 is not less than 25% greater than width w2. In some embodiments, width w3 is not less than 33% greater than width w2. In some embodiments, width w3 is not less than 50% greater than width w2. Lateral widths w3 may be any suitable values. In some embodiments, lateral widths w3 are not less than 40 μm and not more than 50 μm. In some embodiments, lateral widths w3 are about 45 μm. Through glass vias 711, 712, 713 may be distributed in grid 811 at any pitch p3 such as a pitch of not less than 100 μm and not more than 150 μm. In some embodiments, pitch p3 is about 130 μm. Similarly, lateral widths w2 may be any suitable values. In some embodiments, lateral widths w2 are not less than 20 μm and not more than 40 μm. In some embodiments, lateral widths w2 are about 30 μm. Through glass vias 701, 702, 703may be distributed in grid 811 at any pitch p2. In some embodiments, pitch p2 is not less than 45 μm and not more than 65 μm. In some embodiments, pitch p2 is about 55 μm. However, other values of widths w2, w3 and pitches p2, p3 may be attained using the discussed techniques.

In the context of FIG. 8, through glass vias 701, 702, 703 and through glass vias 711, 712, 713 have a substantially circular cross-section. It is noted that the circularity (i.e., measure of closeness to a perfect circle) of the top of through glass vias 701, 702, 703, 711, 712, 713 may be greater than 90%, with more irregularity being evident toward the bottom of through glass vias 701, 702, 703, 711, 712, 713. Furthermore, width variation may be evident in through glass vias 701, 702, 703, 711, 712, 713 due to tapering or even due to process variation. Notably, the width dimensions discussed herein may be taken at or immediately adjacent to first surface 202 of glass substrate 201. As discussed herein below, non-circular flower shaped through glass vias may be deployed in some contexts for improved run-rate and other advantages.

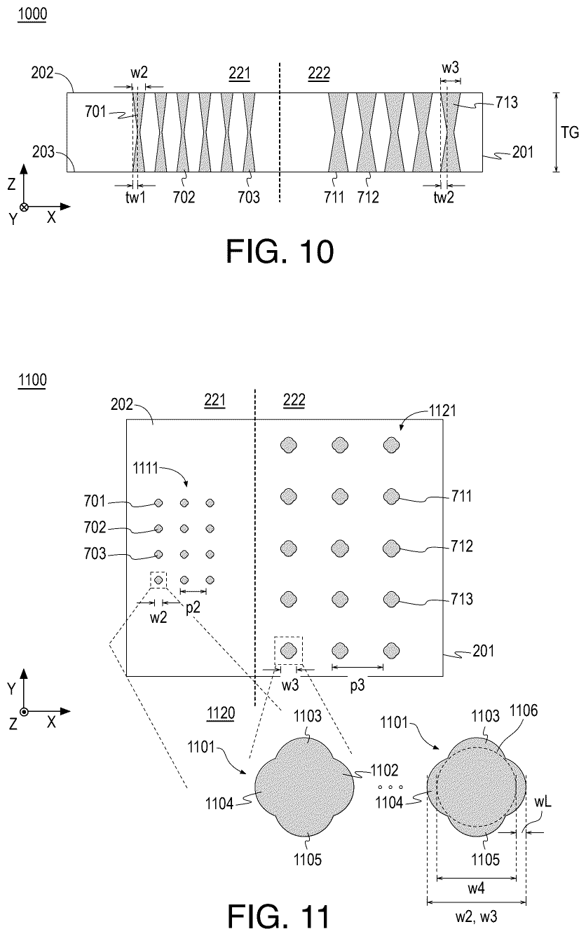

FIG. 9 is a top-down view of laser emission patterns 910, 920, 930 of methods 100 to form heterogeneous through glass vias, such that laser emission patterns 910, 920, 930 may be deployed during a laser exposure such as laser exposures 312, 322, 512, 522 in the context of one or both of operations 102, 104 at some or all of the laser emission positions. For example, any of laser emission patterns 910, 920, 930 may be selectively deployed to form holes for through glass vias. Variation of laser emission patterns 910, 920, 930 may causes variation in via taper (discussed with respect to FIG. 10) and/or cross-sectional via shape (discussed with respect to FIG. 11) and/or size (discussed herein above).

As shown, in some embodiments, a laser exposure at a particular position includes a single lateral position laser emission pattern 910. It is noted that this pattern may be exposed by a laser beam exposure 911 from multiple heights above the glass substrate, with non-circular lateral patterns being evident post-etch. Notably, flower shaped via patterns may be attained using such multiple height exposures including percussive exposure with variable height. In some embodiments, laser emission pattern 910 includes exposure at a first height over the glass substrate a second height over the glass substrate such that the second height is not less than 2.5% greater than the first height. In some embodiments, the second height is not less than 5% greater than the first height. second height is not less than 10% greater than the first height.

In some embodiments a laser exposure at a particular position includes a trepanning lateral position laser emission pattern 920. As discussed, lateral patterns 311, 321, 511, 521 may be deployed during a laser emission (see FIGS. 3 & 5) moving glass substrate 201 relative to laser source 302. Trepanning lateral position laser emission pattern 920 provides multiple laser beam exposures 911 each moved relative to one another in a patter that encircles (and may overlap with) a center point or centerline position 921 of the target position. It is noted that trepanning lateral position laser emission pattern 920 may include varying the exposure height during trepanning. Furthermore, trepanning lateral position laser emission pattern 920 may cause non-circular lateral patterns being evident post-etch. Notably, flower shaped via patterns may be attained using such multiple height exposures including percussive exposure with variable height.

As shown with respect to trepanning lateral position laser emission pattern 920, a discrete number of locations are exposed during the trepanning. The discrete number of locations may be any number such as 8, 10, 12, or more to approximate a substantially continuous outer pattern 922, which may be a circle, oval, or the like. However, in some contexts a lateral position laser emission pattern 930 deployed during exposure uses a similar pattern but fewer discrete exposures. This less approximates substantially continuous outer pattern 922 but offers the advantage of faster throughput due to fewer exposures while providing a high quality through glass via having a lateral cross-sectional shape (i.e., in the x-y plane) that has a flower shape. For example, laser emission patterns 920, 930 include exposing at least one position of the glass substrate with multiple exposures around a centerline position of the at least one position.

For example, lateral patterns 311, 321, 511, 521 including any of laser emission patterns 910, 920, 930 may be deployed to provide heterogenous through glass vias with tuned diameters, cross-sectional shapes, tapers, and so on. In some contexts, some of the resultant through glass vias have circular cross-sectional shapes while others have flower shapes, as discussed herein below. Notably, the resultant flower shapes may be evident in larger vias where the shape is adequate while providing run rate improvement due to the efficiency of multi-exposure processing (either at multiple heights or multiple lateral positions or both) over single exposure processing.

Turning now to taper variation, FIG. 10 is an illustration of a cross-sectional side view of a glass substrate structure 1000 showing through glass vias 701, 702, 703 having dual tapers with a taper width of tw1 and through glass vias 701, 702, 703 having dual tapers with a taper width of tw2. As used herein, taper width indicates a difference between an outer edge at maximum width w2, w3 of a via and an outer edge of a minimum width (not shown) of the via, which is typically at the center of thickness TG of glass substrate 201 in the context of a dual taper. It is noted that a variety of process parameters such as exposure conditions, etchant temperature, presence of a surface coating, and others can impact taper widths.

As discussed with respect to lateral widths, taper widths may be homogeneous (as shown) or heterogenous within region 221. In some embodiments, taper widths tw1 between through glass vias 701, 702, 703 may vary by not less than 5%, not less than 10%, or not less than 20% within region 221 based on exposure differences. Similarly, taper widths tw2 between through glass vias 711, 712, 713 may vary by not less than 5%, not less than 10%, or not less than 20% within region 222 based on exposure differences. Furthermore, between region 222 and region 221, due to double etch processing, taper width tw2 may be greater than taper width tw1. In some embodiments, taper width tw2 is not less than 10% greater than taper width tw1. In some embodiments, taper width tw2 is not less than 15% greater than taper width tw1. In some embodiments, taper width tw2 is not less than 20% greater than taper width tw2. In some embodiments, taper width tw1 is in the range of about 5 to 10 μm and taper width tw2 is int eh range of about 8 to 15 μm, although other widths may be used.

Turning now to through glass via cross-sectional shape variation. As discussed, such variation in the shape of the through glass via is established by laser assisted etch processing (with single or multiple etching), to which the through glass via metallization conforms.

FIG. 11 is a top-down view of a glass substrate structure 1100 such as glass substrate structure 700 having through glass vias 701, 702, 703 in region 221 and through glass vias 711, 712, 713 in region 222 of glass substrate 201 such that through glass vias 701, 702, 703 and through glass vias 711, 712, 713 have a lateral cross-sectional flower shape as shown in enlarged views 1120. In enlarged views 1120, the right view illustrates a central circle overlaid on the cross-sectional shape. Notably, enlarged views 1120 illustrate either or both of through glass vias 701, 702, 703 in region 221 and through glass vias 711, 712, 713 in region 222, such that either or both may have the illustrated characteristics.

As shown, through glass vias 701, 702, 703 and heterogeneous through glass vias 711, 712, 713 may be in any suitable layout such as a grid 1111 of through glass vias 701, 702, 703 and a grid 1121 of through glass vias 711, 712, 713 such that both grids 1111, 1121 have vias with a lateral cross-sectional flower shape. However, other layouts may be used. As used herein, the term lateral cross-section, lateral cross-sectional, and similar terms indicate a cross-section taken with a plane that extends in the lateral direction (i.e., parallel to the x-y plane). In some embodiments, the lateral cross-section is taken at or in close proximity to first surface 202 of glass substrate 201. However, such lateral cross-sectional flower shapes may be evident throughout the thickness of glass substrate 201.

In the context of glass substrate structure 1100, through glass vias 701, 702, 703 are homogeneous, as are through glass vias 711, 712, 713. That is, grid 1111 includes through glass vias 701, 702, 703 of substantially the same sizes and shapes and grid 1121 includes through glass vias 711, 712, 713 of substantially the same sizes and shapes. In some embodiments, grid 1111 includes heterogenous through glass vias 701, 702, 703 of different sizes and/or shapes and/or grid 1121 includes heterogenous through glass vias 711, 712, 713 of different sizes and/or shapes. Also as shown, through glass vias 701, 702, 703 have a cross-sectional width (i.e., diameter) of w2 and a pitch of p2. Through glass vias 711, 712, 713 have a cross-sectional width (i.e., diameter) of w3 and a pitch of p3. Widths w2, w3 and pitches p2, p3 may have any values discussed herein. As used herein, the terms cross-sectional width and diameter indicate a measure that extends through the centroid of the shape and extends to the widest points of the shape.

In the context of FIG. 11, through glass vias 701, 702, 703 and through glass vias 711, 712, 713 have a substantially flower cross-sectional shape. The term flower cross-sectional shape indicates having a multi-lobe (i.e., two or more lobes) shape such that each lobe has a region that extends beyond a center-circle 1106 of the shape. That is, one or more of through glass vias 701, 702, 703 and/or through glass vias 711, 712, 713 may have a multi-lobe shape 1101 taken at a cross-section orthogonal to the thickness of the glass substrate (i.e., in the x-y plane orthogonal to the thickness in the z-dimension) such that each lobe 1102, 1103, 1104, 1105 of multi-lobe shape 1101 extends beyond a center-circle 1106 of multi-lobe shape 1101 (see the right hand illustration of enlarged views 1120.

In some embodiments, multi-lobe shape 1101 has not fewer than four lobes. However, any number of lobes such as two, three, five, six, or more may be used. Center-circle 1106 of multi-lobe shape 1101 may have any suitable cross-sectional width (i.e., diameter) w4. In some embodiments, cross-sectional width w4 is not less than 20 μm and not more than 60 μm. In some embodiments, cross-sectional width w4 is not less than 20 μm and not more than 40 μm. In some embodiments, cross-sectional width w4 is not less than 25 μm and not more than 35 μm. In some embodiments, cross-sectional width w4 is not less than 95% of cross-sectional width w2 or w3. In some embodiments, cross-sectional width w4 is not less than 97.5% of cross-sectional width w2 or w3. In some embodiments, cross-sectional width w4 is not less than 99% of cross-sectional width w2 or w3. Other ratios of center-circle 1106 cross-sectional width w4 to outer cross-sectional width w2, w3 may be used. As shown, each of lobes 1102, 1103, 1104, 1105 extends beyond center-circle 1106 of the multi-lobe shape by a lobe width wL, which may be any suitable value such as not less than 0.5 μm, not less than 1 μm, not less than 2 μm or not less than 5 μm. Each of lobes 1102, 1103, 1104, 1105 intersects an adjacent one of lobes 1102, 1103, 1104, 1105 at a position at our outside of center-circle 1106.

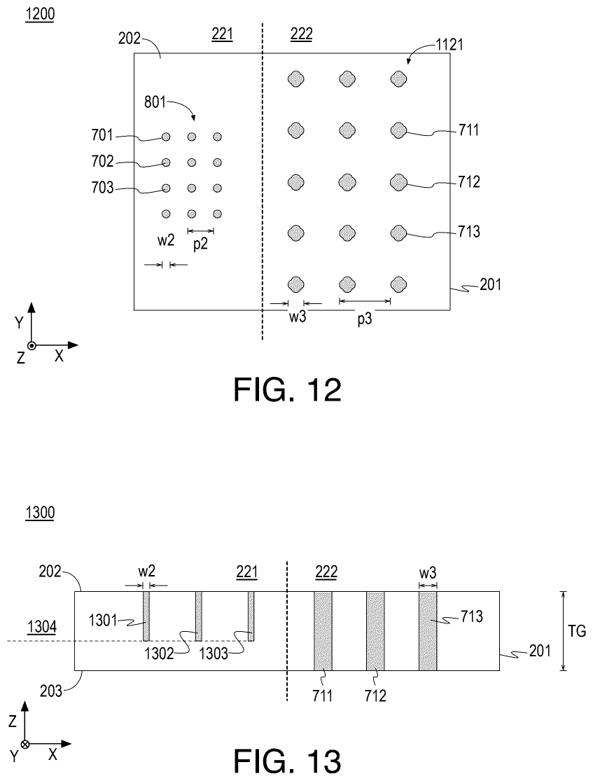

FIG. 12 is a top-down view of a glass substrate structure 1200 such as glass substrate structure 700 having through glass vias 701, 702, 703 in region 221 having substantially circular cross-sectional shapes and through glass vias 711, 712, 713 in region 222 having a lateral cross-sectional flower shape as discussed with respect to FIG. 11. In the context of FIG. 12, through glass vias 701, 702, 703 may have any features or characteristics discussed with respect to FIG. 8 and through glass vias 711, 712, 713 may have any features or characteristics discussed with respect to FIG. 11. Although illustrated with respect to through glass vias 711, 712, 713 in region 222 having a lateral cross-sectional flower shape and through glass vias 701, 702, 703 in region 221 having substantially circular cross-sectional shapes, in alternative embodiments, through glass vias 711, 712, 713 in region 222 have substantially circular cross-sectional shapes and through glass vias 701, 702, 703 in region 221 have a lateral cross-sectional flower shape. In either case, FIG. 12 illustrates that varying cross-sectional shapes may be deployed in the same glass substrate 201 and the heterogenous vias and related processing discussed herein may provide for any shapes (circular, flower, flower with differing numbers of lobes), sizes, tapers, and so on of through glass vias 701, 702, 703, 711, 712, 713.

FIG. 13 is an illustration of a cross-sectional side view of a glass substrate structure 1300 showing blind vias 1301, 1302, 1303 deployed in region 221 of glass substrate 201. As shown, blind vias 1301, 1302, 1303 extend from first surface 202 to a position 1304 only partially through thickness TG of glass substrate 201. Although illustrated with respect to through glass vias in region 222 being blind vias 1301, 1302, 1303 and through glass vias 701, 702, 703 in region 221 being full through via, in alternative embodiments, through glass vias in region 222 are blind vias, or both regions 221, 222 deploy blind vias. Such blind vias may have any characteristics discussed herein with respect to through glass vias 701, 702, 703, 711, 712, 713, and the blind vias may be formed using any suitable technique or techniques such as modification of exposure.

Discussion now turns to use of a patterned layer that is selectively on or over particular via positions and/or has selective thicknesses on or over particular via positions. The patterned layer includes patterned openings and/or patterned thin regions to alter the effective laser exposure transmission to the underlying glass substrate. The patterned layer may be any suitable material that attenuates the exposure transmission to the underlying glass substrate, and the patterned layer may be characterized as a laser attenuation layer. The patterned layer or laser attenuation layer may be deployed as part of operations 102, 104 to alter the exposure between vias to provide heterogenous through glass vias.

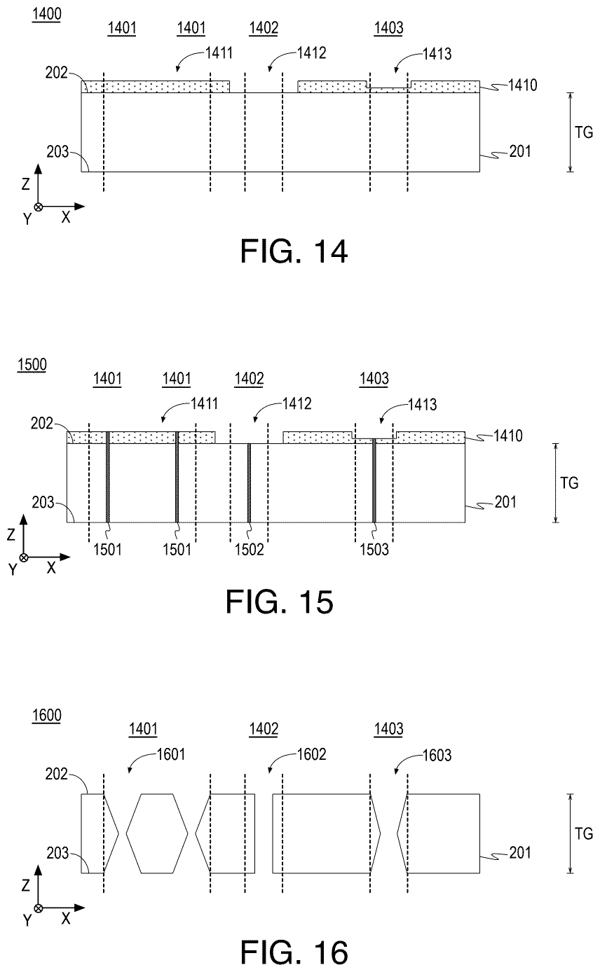

FIG. 14 is an illustration of a cross-sectional side view of a glass substrate structure 1400 similar to glass substrate structure 1400 after formation of patterned layer 1410. Patterned layer 1410 includes regions 1411, 1413 of differing thicknesses and/or exposed regions 1412. Patterned layer 1410 may be formed using any suitable technique or techniques including inkjet printing, screen printing or the like, or bulk layer deposition followed by pattern and etch techniques. Patterned layer 1410 may be any suitable material that is a modest absorber such as a translucent layer for the pertinent laser light being used (e.g., 515 nm laser exposure). Patterned layer 1410 includes regions 1411 at a first thickness such as thicknesses in the range of 1 to 20 μm, depending on material deployed. Patterned layer 1410 further includes regions 1413 at a second thickness that is less than the first thickness and/or regions 1412 that are exposed. The second thickness may be any suitable fraction or percentage of the first thicknesses. In some embodiments, the second thickness is not more than 75% of the first thickness. In some embodiments, the second thickness is not more than 50% of the first thickness. In some embodiments, the second thickness is not more than 25% of the first thickness. Although illustrated with respect to two different thicknesses, any number of differing thicknesses such as three or more may be used.

Patterned layer 1410 may be any suitable material that partially absorbs laser light, as discussed. In some embodiments, patterned layer 1410 is an oxide of a metal. For example, patterned layer 1410 may be zinc oxide (e.g., include zinc and oxygen), aluminum oxide (e.g., include aluminum and oxygen), or titanium oxide (e.g., include titanium and oxygen), or a combination of such materials. In some embodiments, patterned layer 1410 is a polymeric material. For example, patterned layer may be an epoxy material, a polyimide (PI) material, a benzocyclobutene (BCB) based material, a high density polyethylene material (HDPE) material, a polyethylene terephthalate based material, a polyethylene based material, or a photoresist material. In some embodiments, the composition of patterned layer 1410 may include one or more of an organic dielectric material, such as, an epoxy resin, phenolic-glass, or a resinous film such as the GX-series films commercially available from Ajinomoto Fine-Techno Co., Inc. (ABF).

As discussed, these materials are modest absorbers of laser light such as 515 nm laser light used in the discussed laser assisted etch process, and they function to modulate the effective laser dose delivered as a function of thickness. This, in turn, drives the effectiveness of the laser modification to the underlying glass volume of the glass substrate, which changes the resultant hole post-etch and eventual through glass via. In some embodiments, the change is to the taper angle of the resultant through glass via such that a greater thickness will result in a weaker laser dose and thus a higher taper angle relative to a lesser thickness and/or the material not being present. For example, a higher taper angle (and greater taper width) will be evident under regions 1411 of patterned layer 1410 relative to regions 1413 and regions 1412.

FIG. 15 is an illustration of a cross-sectional side view of a glass substrate structure 1500 similar to glass substrate structure 1400 after exposure processing to form modified glass regions 1501, 1502, 1503 within regions 1411, 1412, 1413, respectively, of glass substrate 201. As discussed each exposure modifies glass substrate 201 makes it prone to faster etching during subsequent etch processing. Furthermore, by applying a thicker patterned layer over regions 1411, the resultant exposure to glass substrate 201 is less than that in regions 1503, which is in turn less than that in regions 1412. Due to the variation in resultant exposure, modified glass regions 1501, 1502, 1503 are differently modified as well, leading to differing taper angles post-etch. In some embodiments, each exposure to modified glass regions 1501, 1502, 1503 are advantageously be made with the same conditions, for improved throughput and simplified processing with variation in modified glass regions 1501, 1502, 1503 being made using patterned layer 1410. For example, prior to exposing positions of a glass substrate, a layer may be formed having a first thickness over one or more first positions and a second thickness over one or more second positions such that the layer is an oxide of a metal or a polymeric material that is present during exposure to modify the exposure of the underlying glass substrate.

FIG. 16 is an illustration of a cross-sectional side view of a glass substrate structure 1600 similar to glass substrate structure 1500 after double sided etching to form holes or openings 1601, 1602, 1603. Openings 1601, 1602, 1603 may be formed using any suitable etch processing discussed herein. In the context of FIG. 16, the etch processing is double-sided, from both first surface 202 and second surface 203. In some embodiments, as discussed below, such etch processing is only from second surface 203 (i.e., the etch is a back-side etch). Furthermore, as shown, patterned layer 1410 may be removed in some embodiments. In alternative embodiments, patterned layer 1410 may remain as a protective layer for glass substrate 201.

As shown in FIG. 16, openings 1601 have a greater taper angle than opening 1603. In the context of symmetrical hourglass vias, the term taper angle indicates the angle between a line extending from an edge of a largest cross section (i.e., at first surface 202 or second surface 203) and an edge of a smallest cross section (i.e., at midpoint of thickness TG) and a line orthogonal to first surface 202 or second surface 203 and parallel to the thickness TG of glass substrate 201. In some embodiments, the taper angle of opening 1601 is not less than 50% greater than the taper angle of opening 1603. In some embodiments, the taper angle of opening 1601 is not less than 100% greater than the taper angle of opening 1603. In some embodiments, the taper angle of opening 1601 is not less than 150 greater than the taper angle of opening 1603. In some embodiments, the taper angle of opening 1601 is not less than 200% greater than the taper angle of opening 1603. Similarly, opening 1603 has a greater taper angle than opening 1602, which may have substantially no taper, as shown. It is noted that openings 1601, 1602, 1603 may have any cross-sectional shapes and dimensions discussed herein above.

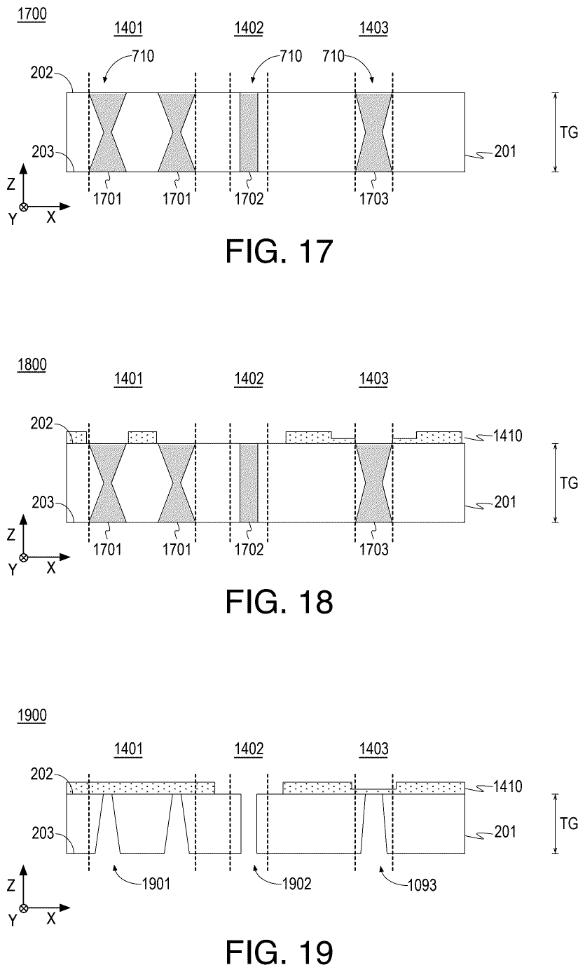

FIG. 17 is an illustration of a cross-sectional side view of a glass substrate structure 1700 similar to glass substrate structure 1600 after formation of metallization 710 to form through glass vias 1701, 1702, 1703 in regions 1401, 1402, 1403, respectively. Metallization 710 may include any materials discussed herein and may be formed using the discussed techniques. Furthermore, through glass vias 1701, 1702, 1703 may include any taper angle, taper width, shapes, and widths discussed herein above. In particular, through glass vias 1701, 1702, 1703 may include the taper angles modified as discussed with respect to FIGS. 15 and 16 due to the presence of patterned layer 1410 during exposure processing.

As discussed, in some embodiments patterned layer 1410 may remain as a partial protective cover for glass substrate 201. FIG. 18 is an illustration of a cross-sectional side view of a glass substrate structure 1800 similar to glass substrate structure 1700 where patterned layer 1410 remains after etch processing. As shown, in regions 1401, 1403, at least portions of patterned layer 1410 remains over first surface 202 of glass substrate 201. Patterned layer 1410 may be partially removed during the etch processing of glass substrate 201 and/or patterned layer 1410 may be removed to expose portions of openings 1601, 1602, 1603 as needed to fabricate through glass vias 1701, 1702, 1703.

As discussed, etch processing may be double-sided, from both first surface 202 and second surface 203, or only from second surface 203 (i.e., the etch is a back-side etch). In such contexts, patterned layer 1410 advantageously provides a protective layer for glass substrate 201 during etch processing and subsequent assembly. FIG. 19 is an illustration of a cross-sectional side view of a glass substrate structure 1900 similar to glass substrate structure 1500 after single sided etching from second surface 203 to form holes or openings 1901, 1902, 1903. Openings 1901, 1902, 1903 may be formed using any suitable etch processing discussed herein. In some embodiments, region 1402, having a fully exposed first surface 202 of glass substrate 201, is not deployed such that patterned layer 1410, at some thickness, is over an entirety of first surface 202 of glass substrate 201.

In the context of FIG. 19, openings 1901 have a greater taper angle than opening 1603. In the context of single sided etch and single taper vias, the term taper angle indicates the angle between a line extending from an edge of a largest cross section (i.e., at second surface 203) and an edge of a smallest cross section (i.e., at first surface 202 or) and a line orthogonal to first surface 202 or second surface 203 and parallel to the thickness TG of glass substrate 201. In some embodiments, the taper angle of opening 1901 is not less than 50% greater than the taper angle of opening 1903. In some embodiments, the taper angle of opening 1901 is not less than 100% greater than the taper angle of opening 1903. In some embodiments, the taper angle of opening 1901 is not less than 150 greater than the taper angle of opening 1903. In some embodiments, the taper angle of opening 1901 is not less than 200% greater than the taper angle of opening 1903. Similarly, opening 1903 has a greater taper angle than opening 1902 (if used), which may have substantially no taper, as shown. As with openings 1601, 1602, 1603, openings 1901, 1902, 1903 may have any cross-sectional shapes and dimensions discussed herein above.

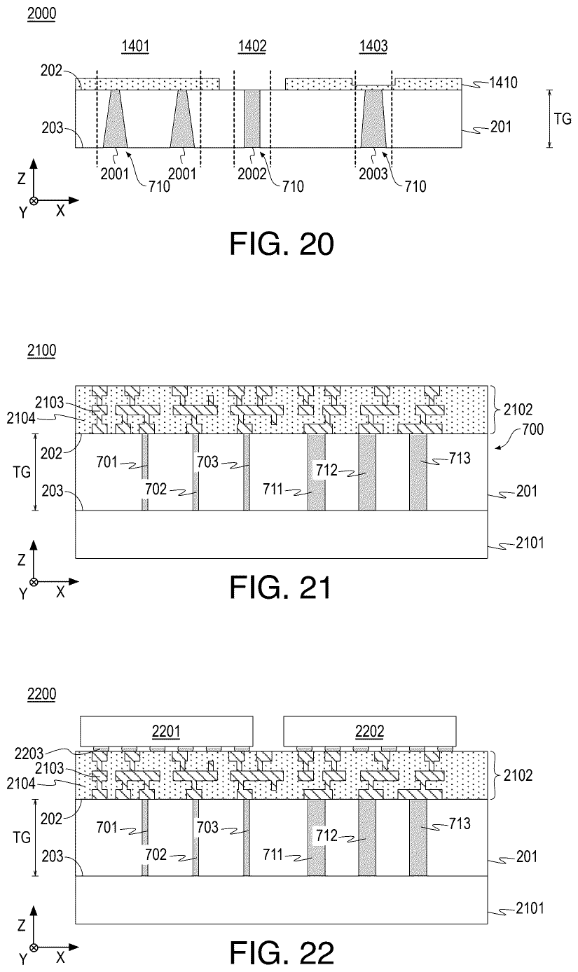

FIG. 20 is an illustration of a cross-sectional side view of a glass substrate structure 2000 similar to glass substrate structure 1900 after formation of metallization 710 to form through glass vias 2001, 2002, 2003 in regions 1401, 1402, 1403, respectively. Metallization 710 may include any materials discussed above such as copper, and may be formed using any of the techniques discussed herein. Furthermore, through glass vias 2001, 2002, 2003 may have any characteristics such as taper angle, taper width, shapes, and widths discussed herein above. In particular, through glass vias 2001, 2002, 2003 may include the taper angles modified as discussed with respect to FIGS. 15 and 16 due to the presence of patterned layer 1410 during exposure processing.

Returning to FIG. 1, methods 100 continue at operation 107, where an electrical routing structure may be built up over at least one side of the glass substrate prior to assembly with an integrated die. The electrical routing structure may be electrically coupled to the through glass vias and may, for example, include one or more levels of metallization features embedded within any suitable dielectric material. The electrical routing structure formed at operation 107 may interconnect one or more IC die to each other and/or couple one or more of IC die to the conductive through vias. Accordingly, the metallization feature pitch of the routing structure is advantageously minimized for highest interconnect density.

FIG. 21 is an illustration of a cross-sectional side view of a package structure 2100 similar to glass substrate structure 700 after attachment of glass substrate structure 700 to a handle or carrier 2101 and fabrication or attachment of routing structure 2102. Although illustrated with respect to incorporation of glass substrate structure 700 into package structures 2100, 2200, 2300, any glass substrate structure may be deployed in package structures 2100, 2200, 2300. Carrier 2101 may have any suitable composition and may be of any suitable thickness. Furthermore, glass substrate structure 700 may be attached to carrier 2101 using any suitable technique or techniques such as a removable adhesive, a releasable tape, or the like.

In some embodiments, routing structure 2102 is built-up over first surface 202. As shown, routing structure 2102 includes one or more levels of redistribution layer (RDL) metallization features 2103 embedded within one or more layers of dielectric material 2104. RDL metallization features 2103 may include any suitable metal such as copper. In some embodiments, a portion of RDL metallization features 2103 are to electrically bridge together two or more IC dies, preferably with a fine metallization feature pitch as enabled by the improved flatness profile of glass substrate 201 as compared to traditional organic preform cores. Furthermore, a portion of routing structure 2102 further include metallization features 2103 that are to interconnect IC dies to conductive through glass vias 701, 702, 703, 711, 712, 713.

Dielectric material 2104 may be any suitable material or materials such as a molding compound, a spin-on material, or a dry film laminate material. In some embodiments, dielectric material 2104 is applied in a wet or uncured state into a cast and is then dried or cured. Alternatively, dielectric material 2104 may be applied as a semi-cured dry film that is fully cured following its application to glass substrate 201. The composition of dielectric material 2104 may include one or more of an organic dielectric material, such as, an epoxy resin, phenolic-glass, or a resinous film such as the GX-series films commercially available from Ajinomoto Fine-Techno Co., Inc. (ABF). Exemplary epoxy resins for deployment in dielectric material 2104 include an acrylate of novolac such as epoxy phenol novolacs (EPN) or epoxy cresol novolacs (ECN). In some embodiments, dielectric material 2104 is a bisphenol-A epoxy resin including epichlorohydrin, for example. In some embodiments, dielectric material 2104 includes an aliphatic epoxy resin.

Returning to FIG. 1, methods 100 continue at operation 108, where at least one IC die is assembled to the workpiece. In some embodiments, the one or more IC dies are attached to the electrical routing structure formed at operation 107. The one or more IC dies assembled at operation 108 may each include any electrical circuitry. In some embodiments, one or more of the IC dies include logic circuitry including logic gates. The one or more IC dies assembled at operation 108 may also include any photonic circuitry suitable for the detection, emission or processing (e.g., filtering, multiplexing and demultiplexing) of optical signals.

FIG. 22 is an illustration of a cross-sectional side view of a package structure 2200 similar to package structure 2100 after attachment of any number of IC dies such as IC dies 2201, 2202 to routing structure 2102 using intervening electrical interconnects 2203. As shown, IC dies 2201, 2202 are assembled to interconnect interfaces within a top metallization level of routing structure 2102 of an assembled package structure 2200. Although illustrated with two IC dies 2201, 2202, package structure 2200 may include any number of IC dies. In some embodiments, IC dies 2201, 2202 are the first level of dies of a packaged multi-die IC device package structure. IC dies 2201, 2202 may be directly bonded to routing structure 2102, or, electrically coupled through intervening electrical interconnects 2203, which may include solder of any suitable composition. In the example illustrated, IC dies 2201, 2202 are each flip-chip attached with integrated circuitry within each die being proximal to a top surface of routing structure 2102. In alternative embodiments, IC dies 2201, 2202 include through die vias (not shown) with integrated circuity being distal from the top surface of routing structure 2102.

IC dies 2201, 2202 may include any suitable circuitry. In some embodiments, at least one of IC dies 2201, 2202 is a fully functional ASIC. In some embodiments, IC dies 2201, 2202 include a chiplet or tile that has more limited functionality supplementing the function of one or more others of IC dies 2201, 2202 that are to be part of the same multi-die device. A chiplet or tile may, for example, be any of a wireless radio circuit, microprocessor core, electronic memory circuit, floating point gate array (FPGA), power management and/or power supply circuit, or a MEMS device. In some examples, one or more of IC dies 2201, 2202 includes one or more banks of active repeater circuitry to improve multi-die interconnects (e.g., network-on-chip architectures). In other examples, one or more of IC dies 2201, 2202 includes clock generator circuitry or temperature sensing circuitry. In other examples, one or more of IC dies 2201, 2202 includes logic circuitry that, along with other IC dies 2201, 2202 implement multi-chiplet aggregated logic circuitry (e.g., mesh network-on-chip architectures). In some specific examples, at least one of IC dies 2201, 2202 includes microprocessor core circuitry, for example including one or more shift registers. IC dies 2201, 2202 may include field effect transistors (FETs) with a device pitch of 80 nm, or less. The FETs may be of any architecture (e.g., planar, non-planar, single-gate, multi-gate, stacked nanosheet, etc.). Additionally or in the alternative, IC dies 2201, 2202 may include active devices other than FETs such as magnetic tunnel junctions (MTJs), capacitors, or the like. In some embodiments, IC dies 2201, 2202 include one or more IC die metallization levels embedded within an insulator.

Returning to FIG. 1, methods 100 continue at operation 109, where the final device is packaged, assembled, and output, for example, by attachment of a package to a host component. The assembly or package may be installed in any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

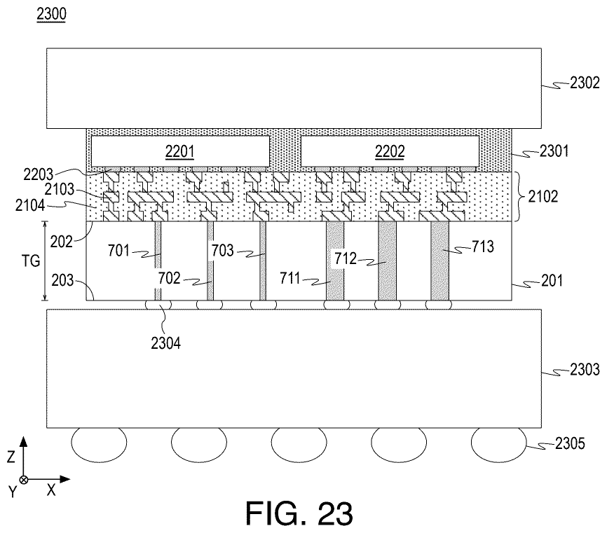

FIG. 23 is an illustration of a cross-sectional side view of a package structure 2300 similar to package structure 2200 after attachment to a host component 2303 and deployment of one or more heat spreaders and/or heat sinks 2302. As shown, package structure 2300, which may be characterized as a system, includes package structure 2200 attached to host component 2303 with interconnects 2304. In some embodiments, interconnects 2304 are solder (e.g., SAC) microbumps although other interconnect features may be used. In some embodiments, host component 2303 is predominantly silicon. Host component 2303 may also include one or more alternative materials known to be suitable as interposers or package substrates (e.g., an epoxy preform, cored or coreless laminate board, etc.). In some embodiments, host component 2303 is a printed circuit board (PCB). In some embodiments, host component 2303 includes one or more metallized redistribution levels (not depicted) embedded within a dielectric material. Host component 2303 may also include one or more IC dies, one or more passive or active components, or the like embedded therein.

Host component 2303 may include interconnects 2305 which may include solder (e.g., ball, bump, etc.) suitable for a given host board architecture (e.g., surface mount FR4, etc.). Also as shown, one or more heat spreaders and/or heat sinks 2302 may be coupled to package structure 2200, which may be advantageous, for example, where IC dies 2201, 2202 include one or more CPU cores or other circuitry of similar power density. Any package dielectric 2301, such as a mold material, may surround sidewalls of IC dies 2201, 2202. Although not illustrated, package dielectric 2301 may be ground down to a top surface of IC dies 2201, 2202 such that heat spreader/sink 2302 may be in closer contact with IC dies 2201, 2202.

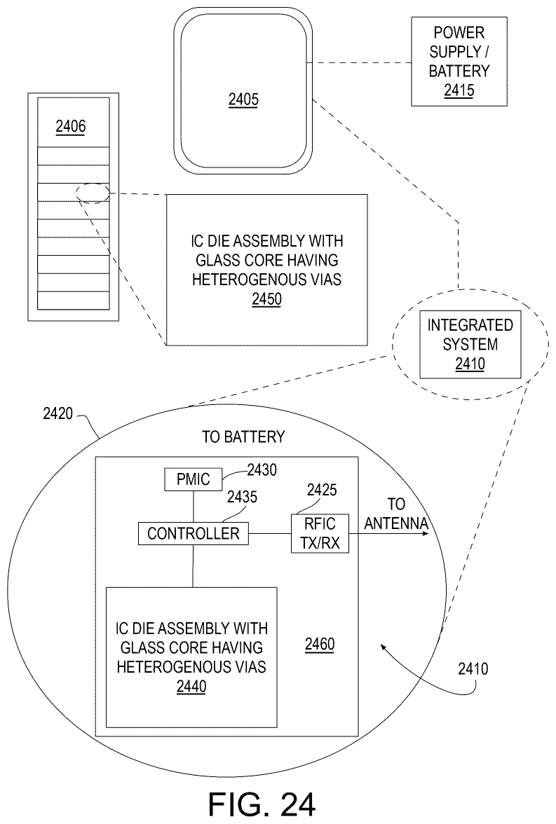

FIG. 24 illustrates exemplary systems employing an IC assembly including a glass core substrate with heterogenous through glass vias, arranged in accordance with at least some implementations of the present disclosure. The system may be a mobile computing platform 2405 and/or a data server machine 2406, for example. Either may employ a component assembly including an IC assembly including a glass core substrate with heterogenous through glass vias as described elsewhere herein. Server machine 2406 may be any commercial server, for example including any number of high-performance computing platforms disposed within a rack and networked together for electronic data processing, which in the exemplary embodiment includes an IC die assembly 2450 with a glass core substrate with heterogenous through glass vias as described elsewhere herein. Mobile computing platform 2405 may be any portable device configured for each of electronic data display, electronic data processing, wireless electronic data transmission, or the like. For example, mobile computing platform 2405 may be any of a tablet, a smart phone, a laptop computer, etc., and may include a display screen (e.g., a capacitive, inductive, resistive, or optical touchscreen), a chip-level or package-level integrated system 2410, and a battery 2415 and/or power supply circuitry. Although illustrated with respect to mobile computing platform 2405, in other examples, chip-level or package-level integrated system 2410 and battery 2415 may be implemented in a desktop computing platform, an automotive computing platform, an internet of things platform, or the like. As discussed below, in some examples, the disclosed systems may include a sub-system 2460 such as a system on a chip (SOC) or an integrated system of multiple ICs, which is illustrated with respect to mobile computing platform 2405.

Whether disposed within integrated system 2410 illustrated in expanded view 2420 or as a stand-alone packaged device within data server machine 2406, sub-system 2460 may include memory circuitry and/or processor circuitry 2440 (e.g., RAM, a microprocessor, a multi-core microprocessor, graphics processor, etc.), a power management integrated circuit (PMIC) 2430, a controller 2435, and a radio frequency integrated circuit (RFIC) 2425 (e.g., including a wideband RF transmitter and/or receiver (TX/RX)). As shown, one or more IC dies, such as memory circuitry and/or processor circuitry 2440 may be assembled and implemented such that one or more have an IC assembly including a glass core substrate with heterogenous through glass vias as described herein. In some embodiments, RFIC 2425 includes a digital baseband and an analog front-end module further including a power amplifier on a transmit path and a low noise amplifier on a receive path. Functionally, PMIC 2430 may perform battery power regulation, DC-to-DC conversion, etc., and so has an input coupled to battery 2415, and an output providing a current supply to other functional modules. As further illustrated in FIG. 24, in the exemplary embodiment, RFIC 2425 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2440 may provide memory functionality for sub-system 2460, high level control, data processing and the like for sub-system 2460. In alternative implementations, each of the SOC modules may be integrated onto separate ICs coupled to a package substrate, interposer, or board.

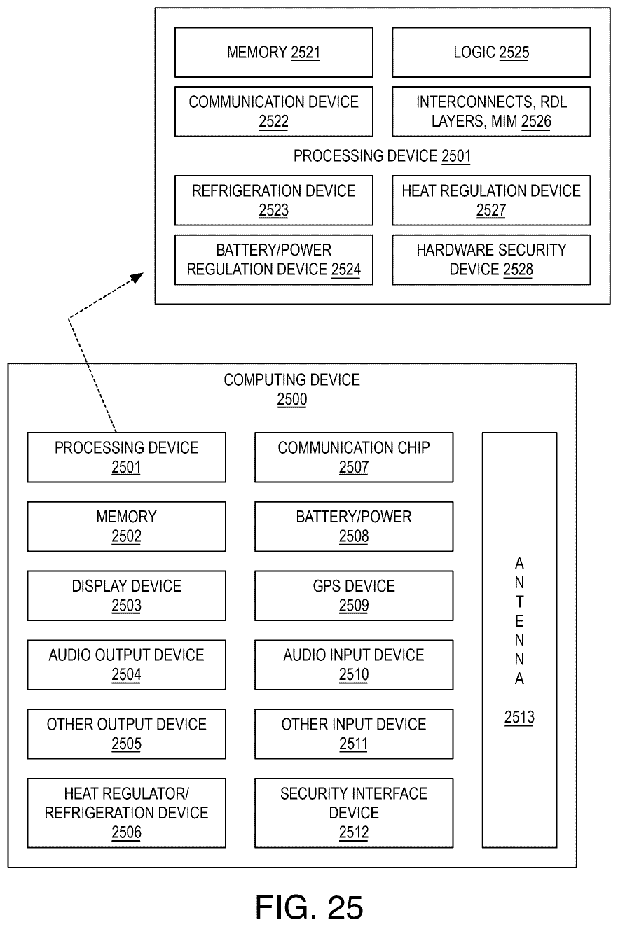

FIG. 25 is a block diagram of a computing device 2500, in accordance with some embodiments. For example, one or more components of computing device 2500 may include any of the package structures or assemblies having a glass core substrate with heterogenous through glass vias as discussed elsewhere herein. A number of components are illustrated in FIG. 25, but any one or more of these components may be omitted or duplicated, as suitable for the application. In some embodiments, some of the components included in computing device 2500 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include a glass core substrate with heterogenous through glass vias, for example, as discussed herein. Additionally, in various embodiments, computing device 2500 may not include one or more of the components illustrated in FIG. 25, but computing device 2500 may include interface circuitry for coupling to the one or more components. For example, computing device 2500 may not include a display device 2503, but may include display device interface circuitry (e.g., a connector and driver circuitry) to which display device 2503 may be coupled.

Computing device 2500 may include a processing device 2501 (e.g., one or more processing devices). As used herein, the term processing device or processor indicates a device that processes electronic data from registers and/or memory to transform that electronic data into other electronic data that may be stored in registers and/or memory. Processing device 2501 may include a memory 2521, a communication device 2522, a refrigeration/active cooling device 2523, a battery/power regulation device 2524, logic 2525, interconnects 2526, a heat regulation device 2527, and a hardware security device 2528.

Processing device 2501 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 2501 may include a memory 2502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 2501 shares a package with memory 2502. This memory may be used as cache memory and may include embedded dynamic random-access memory (eDRAM) or spin transfer torque magnetic random-access memory (STT-M RAM).

Computing device 2500 may include a heat regulation/refrigeration device 2506. Heat regulation/refrigeration device 2506 may maintain processing device 2501 (and/or other components of computing device 2500) at a predetermined low temperature during operation. This predetermined low temperature may be any temperature discussed elsewhere herein.

In some embodiments, computing device 2500 may include a communication chip 2507 (e.g., one or more communication chips). For example, the communication chip 2507 may be configured for managing wireless communications for the transfer of data to and from computing device 2500. The term “wireless” and its derivatives may be used to describe circuits, devices, systems, methods, techniques, communications channels, etc., that may communicate data through the use of modulated electromagnetic radiation through a nonsolid medium.

Computing device 2500 may include any photonics structure discussed herein that may facilitate communication between one or more instances of processing device 2501 and/or one or more instances of memory 2502, for example.

Computing device 2500 may include battery/power circuitry 2508. Battery/power circuitry 2508 may include one or more energy storage devices (e.g., batteries or capacitors) and/or circuitry for coupling components of computing device 2500 to an energy source separate from computing device 2500 (e.g., AC line power).

Computing device 2500 may include a display device 2503 (or corresponding interface circuitry, as discussed above). Display device 2503 may include any visual indicators, such as a heads-up display, a computer monitor, a projector, a touchscreen display, a liquid crystal display (LCD), a light-emitting diode display, or a flat panel display, for example.

Computing device 2500 may include an audio output device 2504 (or corresponding interface circuitry, as discussed above). Audio output device 2504 may include any device that generates an audible indicator, such as speakers, headsets, or earbuds, for example.

Computing device 2500 may include an audio input device 2510 (or corresponding interface circuitry, as discussed above). Audio input device 2510 may include any device that generates a signal representative of a sound, such as microphones, microphone arrays, or digital instruments (e.g., instruments having a musical instrument digital interface (MIDI) output).

Computing device 2500 may include a global positioning system (GPS) device 2509 (or corresponding interface circuitry, as discussed above). GPS device 2509 may be in communication with a satellite-based system and may receive a location of computing device 2500, as known in the art.

Computing device 2500 may include another output device 2505 (or corresponding interface circuitry, as discussed above). Examples include an audio codec, a video codec, a printer, a wired or wireless transmitter for providing information to other devices, or an additional storage device.

Computing device 2500 may include another input device 2511 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2500 may include a security interface device 2512. Security interface device 2512 may include any device that provides security measures for computing device 2500 such as intrusion detection, biometric validation, security encode or decode, managing access lists, malware detection, or spyware detection.

Computing device 2500 may include an antenna 2513. Antenna 2513 may include any device that translates electrical current to radio waves and/or translates radio waves to electrical current.

Computing device 2500, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a glass substrate having a thickness extending between a first surface and an opposing second surface of the glass substrate, a plurality of holes extending at least partially through the thickness of the glass substrate, and a via metallization within each of the holes, such that a first via metallization within a first hole has a multi-lobe shape taken at a cross-section orthogonal to the thickness of the glass substrate, each lobe of the multi-lobe shape extending beyond a center-circle of the multi-lobe shape.

In one or more second embodiments, further to the first embodiments, a second via metallization within a second hole has a second multi-lobe shape taken at the cross-section, and such that a first width of the multi-lobe shape is not less than 25% greater than a second width of the second multi-lobe shape.

In one or more third embodiments, further to the first or second embodiments, a second via metallization within a second hole has a substantially circular shape taken at the cross-section.

In one or more fourth embodiments, further to the first through third embodiments, a first width of the multi-lobe shape is not less than 25% greater than a second width of the circular shape.

In one or more fifth embodiments, further to the first through fourth embodiments, the multi-lobe shape has not fewer than four lobes, the center-circle of the multi-lobe shape is not less than 20 μm and not more than 40 μm, and each of the lobes extend beyond the center-circle of the multi-lobe shape by not less than 1 μm.

In one or more sixth embodiments, further to the first through fifth embodiments, the via metallization and the first hole extend from the first surface to the second surface of the glass substrate, and such that a second via metallization within a second hole is a blind via that extends from the first surface and terminates at a position between the first surface and the second surface.

In one or more seventh embodiments, further to the first through sixth embodiments, the second via metallization has a substantially circular shape taken at the cross-section.

In one or more eighth embodiments, further to the first through seventh embodiments, the apparatus further comprises an integrated circuit (IC) die over the first surface of the glass substrate, such that the IC die is electrically coupled to the via metallization and the glass substrate is a layer of glass having a thickness of not less than 50 μm, a first length of not less than 10 mm and a second length orthogonal to the first length of not less than 10 mm.

In one or more ninth embodiments, a system comprises a package substrate according to any of the apparatuses of the first through seventh embodiments, one or more IC dies coupled to the package substrate and/or a power supply coupled to the package substrate.

In one or more tenth embodiments, a glass substrate having a substrate thickness extending between a first surface and an opposing second surface of the glass substrate, a plurality of holes extending at least partially through the substrate thickness of the glass substrate, a via metallization within each of the holes, and a layer on the first surface of the glass substrate, such that a first via metallization having a first taper within a first hole, the first via metallization under a first region of the first surface, the first region at least partially covered by a first thickness of the layer, and a second via metallization having a second taper or no taper within a second hole, the second via metallization under a second region of the first surface, the second region covered by a second thickness of the layer or absent the layer.

In one or more eleventh embodiments, further to the tenth embodiments, the layer comprises an oxide of a metal.

In one or more twelfth embodiments, further to the tenth or eleventh embodiments, the metal is one of zinc, aluminum, or titanium.

In one or more thirteenth embodiments, further to the tenth through twelfth embodiments, the layer is a polymeric material.

In one or more fourteenth embodiments, further to the tenth through thirteenth embodiments, the polymeric material comprises one of an epoxy material, a polyimide material, a benzocyclobutene based material, a polyethylene terephthalate based material, or a polyethylene based material.

In one or more fifteenth embodiments, further to the tenth through fourteenth embodiments, the first taper comprises a decreasing cross-sectional size of the first via metallization from the second surface toward the first surface

In one or more sixteenth embodiments, further to the tenth through fifteenth embodiments, the apparatus further comprises an integrated circuit (IC) die over the first surface of the glass substrate, such that the IC die is electrically coupled to the via metallization and the glass substrate is a layer of glass having a thickness of not less than 50 μm, a first length of not less than 10 mm and a second length orthogonal to the first length of not less than 10 mm.

In one or more seventeenth embodiments, a system comprises a package substrate according to any of the apparatuses of the tenth through fifteenth embodiments, one or more IC dies coupled to the package substrate and/or a power supply coupled to the package substrate.

In one or more eighteenth embodiments, a method comprises exposing a plurality of first positions of a glass substrate with a laser light emission, etching a first hole corresponding to each of the first positions, exposing a plurality of second positions of the glass substrate with a laser light emission, simultaneously etching a second hole corresponding to each of the second positions while further etching each of the first holes, and filling the first and second holes with via metallization, such that first vias within the first holes have a greater width than second vias within the second holes.

In one or more nineteenth embodiments, further to the eighteenth embodiments, exposing at least one position of the first positions or the second positions comprises exposure with the laser light emission at a first distance over a top surface of the glass substrate and exposure with a second laser light emission at a second distance over the top surface, and such that the second distance is not less than 5% greater than the first distance.

In one or more twentieth embodiments, further to the eighteenth or nineteenth embodiments, exposing at least one position of the first positions or the second positions comprises multiple exposures around a centerline position of the at least one position.

In one or more twenty-first embodiments, further to the eighteenth through twentieth embodiments, the method further comprises forming, prior to said exposing the first positions or said exposing the second positions, forming a layer at a first thickness over only a subset of the first positions or the second positions, the layer comprising an oxide of a metal or a polymeric material, such that the layer is present during said exposing the first positions or said exposing the second positions.

In one or more twenty-second embodiments, further to the eighteenth through twenty-first embodiments, said forming the layer comprises forming the layer at a second thickness over a second subset of the first positions or the second positions and leaving a top surface exposed for a third subset of the first positions or the second positions.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a glass substrate having a thickness extending between a first surface and an opposing second surface of the glass substrate;
a plurality of holes extending at least partially through the thickness of the glass substrate; and
a via metallization within each of the holes, wherein a first via metallization within a first hole has a multi-lobe shape taken at a cross-section orthogonal to the thickness of the glass substrate, each lobe of the multi-lobe shape extending beyond a center-circle of the multi-lobe shape.

2. The apparatus of claim 1, wherein a second via metallization within a second hole has a second multi-lobe shape taken at the cross-section, and wherein a first width of the multi-lobe shape is not less than 25% greater than a second width of the second multi-lobe shape.

3. The apparatus of claim 1, wherein a second via metallization within a second hole has a substantially circular shape taken at the cross-section.

4. The apparatus of claim 3, wherein a first width of the multi-lobe shape is not less than 25% greater than a second width of the circular shape.

5. The apparatus of claim 1, wherein the multi-lobe shape has not fewer than four lobes, the center-circle of the multi-lobe shape is not less than 20 μm and not more than 40 μm, and each of the lobes extend beyond the center-circle of the multi-lobe shape by not less than 1 μm.

6. The apparatus of claim 1, wherein the via metallization and the first hole extend from the first surface to the second surface of the glass substrate, and wherein a second via metallization within a second hole is a blind via that extends from the first surface and terminates at a position between the first surface and the second surface.

7. The apparatus of claim 6, wherein the second via metallization has a substantially circular shape taken at the cross-section.

8. The apparatus of claim 1, further comprising:
an integrated circuit (IC) die over the first surface of the glass substrate, wherein the IC die is electrically coupled to the via metallization and the glass substrate is a layer of glass having a thickness of not less than 50 μm, a first length of not less than 10 mm and a second length orthogonal to the first length of not less than 10 mm.

9. An apparatus, comprising:
a glass substrate having a substrate thickness extending between a first surface and an opposing second surface of the glass substrate;
a plurality of holes extending at least partially through the substrate thickness of the glass substrate;
a via metallization within each of the holes; and
a layer on the first surface of the glass substrate, wherein:
a first via metallization having a first taper within a first hole, the first via metallization under a first region of the first surface, the first region at least partially covered by a first thickness of the layer, and
a second via metallization having a second taper or no taper within a second hole, the second via metallization under a second region of the first surface, the second region covered by a second thickness of the layer or absent the layer.

10. The apparatus of claim 9, wherein the layer comprises an oxide of a metal.

11. The apparatus of claim 10, wherein the metal is one of zinc, aluminum, or titanium.

12. The apparatus of claim 9, wherein the layer is a polymeric material.

13. The apparatus of claim 12, wherein the polymeric material comprises one of an epoxy material, a polyimide material, a benzocyclobutene based material, a polyethylene terephthalate based material, or a polyethylene based material.

14. The apparatus of claim 10, wherein the first taper comprises a decreasing cross-sectional size of the first via metallization from the second surface toward the first surface.

15. The apparatus of claim 1, further comprising:
an integrated circuit (IC) die over the first surface of the glass substrate, wherein the IC die is electrically coupled to the via metallization and the glass substrate is a layer of glass having a thickness of not less than 50 μm, a first length of not less than 10 mm and a second length orthogonal to the first length of not less than 10 mm.

16. A method, comprising:
exposing a plurality of first positions of a glass substrate with a laser light emission;
etching a first hole corresponding to each of the first positions;
exposing a plurality of second positions of the glass substrate with a laser light emission;
simultaneously etching a second hole corresponding to each of the second positions while further etching each of the first holes; and
filling the first and second holes with via metallization, wherein first vias within the first holes have a greater width than second vias within the second holes.

17. The method of claim 16, wherein exposing at least one position of the first positions or the second positions comprises exposure with the laser light emission at a first distance over a top surface of the glass substrate and exposure with a second laser light emission at a second distance over the top surface, and wherein the second distance is not less than 5% greater than the first distance.

18. The method of claim 16, wherein exposing at least one position of the first positions or the second positions comprises multiple exposures around a centerline position of the at least one position.

19. The method of claim 16, further comprising:
forming, prior to said exposing the first positions or said exposing the second positions, forming a layer at a first thickness over only a subset of the first positions or the second positions, the layer comprising an oxide of a metal or a polymeric material, wherein the layer is present during said exposing the first positions or said exposing the second positions.

20. The method of claim 19, wherein said forming the layer comprises forming the layer at a second thickness over a second subset of the first positions or the second positions and leaving a top surface exposed for a third subset of the first positions or the second positions.
